(19) United States
(12) Patent Application Publication
(10) Pub. No.: US 2019/0334042 A1
(43) Pub. Date: Oct. 31, 2019

(54) TRANSPARENT CONDUCTING FILM BASED ON ZINC OXIDE

(71) Applicant: UNIVERSITÉ DU LUXEMBOURG, Esch-Sur-Alzette (LU)

(72) Inventors: Matej HALA, Belvaux (LU); Susanne SIEBENTRITT, Belvaux (LU); Phillip DALE, Belvaux (LU)

(73) Assignee: UNIVERSITÉ DU LUXEMBOURG, Esch-Sur-Alzette (LU)

(21) Appl. No.: 16/303,489

(22) PCT Filed: May 18, 2017
(86) PCT No.: PCT/EP2017/062005

§ 371 Date: Nov. 20, 2018

(30) Foreign Application Priority Data
May 20, 2016 (LU) 93080

(51) Int. Cl. H01L 31/0224; H01B 5/14; H01B 1/08; C23C 14/34; C23C 14/08

(52) U.S. Cl. CPC H01L 31/022483; H01B 5/14; H01B 1/08; H01L 31/0322; C23C 14/086; C23C 14/3492; C23C 14/345

(57) ABSTRACT

A transparent conducting film including a nominally undoped conducting ZnO base layer covered with a ZnO cover. The ZnO base layer has a preferred crystallographic orientation, whereas the ZnO cover includes one or more ZnO sublayers, of which at least one has a crystallographically randomly oriented or amorphous structure or a preferred crystallographic orientation different from the preferred crystallographic orientation of the base layer. The invention further relates to a process for the manufacture of such a transparent conducting film.

### FIELD OF THE INVENTION

The invention generally relates to transparent conducting films, in particular transparent conducting oxide (TCO) films based on ZnO. TCO films according to the invention may be used in various applications, for instance, in electronic or semiconductor devices (e.g. liquid-crystal displays, touchscreens, light emitting diodes, etc.), photovoltaics (e.g. solar panels), or the like.

### BACKGROUND OF THE INVENTION

Transparent conducting oxide (TCO) films are components of numerous semiconductor devices, such as light emitting diodes, touch displays and thin film solar cells. ZnO-based TCO films represent an affordable alternative to expensive In₂O₃:Sn (indium tin oxide, in short: ITO) films. The most common variation is Al-doped ZnO (ZnO:Al) that is highly conducting, highly transparent in the visible (VIS) spectral region and partly transparent in the in the near infrared (NIR) spectral region. A description of the electrical properties of ZnO can be found, e.g. in K. Ellmer, “Electrical properties,” in Ellmer K., Klein A., and Rech B., editors, Transparent Conducting Zinc Oxide: Basics and Applications in Thin Film Solar Cells, pages 34-78. Springer, Berlin, 2008.

A first alternative to ZnO:Al is Boron-doped ZnO (ZnO:B), which exhibits comparably high conductivity but better NIR transparency. Another important alternative to ZnO:Al is nominally undoped but conducting ZnO that also exhibits significantly higher NIR transparency than ZnO:Al and comparable conductivity. For reference, see e.g. above-mentioned book chapter by Ellmer, T. Minami et al., Appl. Phys. Lett. 41, 958 (1982), H. Nanto et al., J. Appl. Phys. 55, 1029 (1984), or J. B. Webb et al., Appl. Phys. Lett. 39, 640 (1981).

A key advantage of ZnO:Al and undoped ZnO films is their ability of being prepared by planar magnetron sputtering, a technique that allows large area coating at low deposition temperatures. This permits fast throughput and a large deposition process flexibility favoured by the industry.

Nominally undoped ZnO films can be made conducting by immersion into a plasma in the vicinity of the growing ZnO film, or by a post-deposition treatment.

Plasma exposure of the growing ZnO film can be achieved by an additional radio frequency (RF)-powered discharge operated above the substrate surface. This technique is described, for instance, in the above-mentioned paper by Webb et al., in D. K. Murti, Applications of Surface Science 11/12, 308 (1982), in M. J. Brett et al., J. Vac. Sci. Technol. A 1, 352 (1983), and in M. Hála et al., Prog. Photovolt: Res. Appl. 23, 1630 (2015). According to another technique, the magnetized plasma is guided from the magnetron (target) region towards the substrate by means of a solenoid (see e.g. the papers by Minami et al. (1982) and Nanto et al. (1984)). In some cases, hydrogen is added into the sputtering gas (that is otherwise pure Ar) in order to induce or enhance resulting ZnO film conductivity.

Known post-deposition treatments for turning nominally undoped ZnO films conducting include exposure of the prepared ZnO films to hydrogen-containing environment (see e.g. S. J. Baik et al., Appl. Phys. Lett. 70, 3516 (1997), and S. Kohiki et al., Appl. Phys. Lett. 64, 2876 (1994)) or to near-ultraviolet light (see e.g. A. Illiberi et al., Prog. Photovolt: Res. Appl. 21, 1559 (2013).

The commonly used ZnO:Al has a major drawback in the pronounced light absorption in NIR spectral region, owing to the significant free carrier absorption caused by abundant electron concentration within its conduction band. This is detrimental in those applications where NIR transparency is of importance. For instance, the ZnO:Al contact layer lowers the amount of light that can be used for effective energy conversion in thin film solar cells based on CuInₓGa₍₁₋ₓ₎(SSe)₂ and CuZnSn(SSe)₄ absorbers featuring low band gap (e.g., 1 eV). An alternative to ZnO:Al having improved transparency in the NIR spectral region would thus be welcomed.

A drawback of the known ZnO-based layers is their limited environmental stability, which is typically reflected by pronounced drop in film conductivity, a property of utmost importance for the functioning of any device. This is specifically pronounced at elevated temperatures (e.g., >80° C.) and in the damp heat (DH) conditions commonly employed by the photovoltaic (PV) industry to test long term air stability (typically 85° C. and 85% relative humidity, as described in the environmental test specification IEC 61646). Conductivity decrease in ZnO-based layers exposed to DH conditions can be explained on the one hand by the inherent susceptibility of ZnO material to water-related degradation (see e.g. F. J. Pern et al., “Degradation of ZnO-based window layers for thin-film CIGS by accelerated stress exposures,” Proc. SPIE 7048, Reliability of Photovoltaic Cells, Modules, Components, and Systems, 7048:70480P, 2008 and J. Huepkes et al., Thin Solid Films 555, 48 (2014), International Symposia on Transparent Conducting Materials, 2012) and on the other hand by the columnar microstructure commonly observed for polycrystalline ZnO films grown from vapour phase (see e.g. F. C. M. Pol. et al., “R. F. Planar Magnetron Sputtered ZnO Films I: Structural Properties”, Thin Solid Films, 204, 349-364, and Y. Kajikawa, J. Crys. Growth 289, 387 (2006). In fact, the columnar and extended grain boundaries may represent pathways for penetration of water and other corroding agents deep into the film, especially if the ZnO film is grown atop rough substrates (see e.g. D. Greiner et al., Thin Solid Films, 517, 2291 (2009)).

Nominally undoped ZnO films are prone to faster degradation (their resistivity rises at a faster pace) than ZnO:Al films even at relatively low (e.g., ambient) temperatures. For example, ZnO films that were treated by H during or after their deposition were found to be not stable, which seems to be due to reoxidation (see the above-cited book chapter by Ellmer). ZnO films treated by post-deposition UV illumination required encapsulation by Al₂O₃ layer immediately after fabrication in order for them to remain conducting in ambient air (see above cited paper by Illiberi (2013)). It can thus be stated that the major limiting factor for industrial application of the nominally undoped ZnO layers is their limited lower environmental stability.

### SUMMARY OF THE INVENTION

It is an object of an aspect of the invention to provide a TCO film based on nominally undoped ZnO with enhanced environmental stability.

An object of a further aspect of the present invention is to provide a method for growing nominally undoped ZnO thin films with improved suitability for industrial production.

A transparent conducting film according to a first aspect of the invention comprises a nominally undoped conducting ZnO base layer covered with a ZnO cover. The ZnO base layer has a preferred crystallographic orientation, whereas the ZnO cover comprises one or more ZnO sublayers, of which at least one has a crystallographically randomly oriented or amorphous structure or a preferred crystallographic orientation different from the preferred crystallographic orientation of the base layer.

As used herein, the term “conducting” designates materials having an electrical resistivity of 10⁻² Ωcm or less.

In the context of the present document, the term “base layer” designates a first layer and the term “cover” designates a second layer, which is applied on the first layer. Both terms are not intended to imply any specific orientation in space or any order of application on the substrate. In an embodiment of the transparent conducting film, however, the cover layer is applied on (preferably directly on, i.e. in direct contact with) the base layer after application of the base layer on the substrate. Also, the base layer may be of greater thickness than the cover layer. The term “cover” is not intended to automatically imply that it is exposed to the atmosphere, i.e. there could be one or more further layers (of different material) applied on the cover layer. Nevertheless, in certain applications, the cover layer may be the topmost layer.

The preferred crystallographic orientation (also: crystallographic preferred orientation, CPO, or crystalline texture) of thin film polycrystalline materials has an influence on the properties (e.g. conductivity, transparency, etc.) of the film because electrical, optical, and mechanical properties are often anisotropic. A transparent conducting film according to the first aspect of the invention combines a first ZnO layer having first preferred crystallographic orientation with at least one second ZnO layer having a second preferred crystallographic orientation, different from the first preferred crystallographic orientation or a crystallographically randomly oriented or amorphous structure. Both the base layer and the cover layer are nominally undoped, which means that they are undoped, except for technically unavoidable residual impurities (e.g., below 0.1 mol-%).

It has been found that combining two differently textured ZnO layers may lead to significant improvement of the environmental stability of the transparent conducting film, especially in terms of electrical conductivity. As a result, a transparent conducting film is now available that has good transparency in the visible (VIS) spectral range (from 380 to 700 nm) and improved transparency in the NIR spectral range (from 700 to 3000 nm) with respect to ZnO:Al films and that can at least compete with the latter in terms of environmental stability.

According to an embodiment of the transparent conducting film, the ZnO cover consists of a single ZnO sublayer. The single ZnO sublayer of the cover could have a crystallographically randomly oriented or amorphous structure or a preferred crystallographic orientation different from that of the ZnO base.

According to another embodiment of the transparent conducting film, the ZnO cover is a multilayer cover comprising plural ZnO sublayers. The ZnO sublayers of the ZnO cover may have different preferred crystallographic orientations. Additionally or alternatively, at least one of the ZnO sublayers of the ZnO cover has a crystallographically randomly oriented or amorphous structure.

According to an embodiment of the transparent conducting film, the ZnO base layer has a thickness comprised in the range from 300 nm to 1.5 μm.

Preferably, at least one of the plural ZnO sublayers of the ZnO cover has a thickness comprised in the range from 2 nm to 40 nm.

The overall thickness of the ZnO cover is preferably comprised in the range from 10 nm to 200 nm.

According to an embodiment of the transparent conducting film, the preferred crystallographic orientation of the ZnO base is (001) with respect to the base layer normal (i.e. the (001) direction corresponds to the thickness direction of the ZnO base layer).

Preferably, the preferred crystallographic orientation of at least one of the ZnO sublayers of the ZnO cover is (110) or (101) with respect to the base layer normal (and the ZnO cover normal).

The transparent conducting film may include a substrate (e.g. a flexible substrate) carrying the ZnO base layer and the ZnO cover applied on the ZnO base layer.

A further aspect of the invention relates to a semiconductor device comprising a transparent conducting film as described hereinabove. The semiconductor device may comprise, e.g., a transparent transistor, an array of transparent transistors, a flat panel display, an RFID chip, a photovoltaic cell and/or a capacitive sensor. Preferably, the semiconductor device is realised in thin-film technology.

According to an embodiment, the semiconductor device comprises a thin-film solar cell, e.g. using an absorber layer of CuInₓGa₍₁₋ₓ₎(SSe)₂ or Cu₂ZnSn(SSe)₄, where x is comprised in the range from 0 to 1.

Another aspect of the invention relates to a method of manufacturing a transparent conducting film as described hereinabove. The method comprises depositing a nominally undoped conducting ZnO base layer and a nominally undoped ZnO cover on the ZnO base by sputtering (preferably magnetron sputtering) from a ZnO target in an inert gas (e.g. Ar) atmosphere or from a Zn target in a mixed oxygen and inert gas atmosphere onto a substrate while maintaining a plasma close to the substrate. In the context of the present document, “close to the substrate” designates the region in the nearest proximity of the substrate and which extends, for instance, a few or several centimetres from the substrate surface towards the primary (sputtering) plasma source. The densities of the plasma close to the substrate are selected different for the deposition of the ZnO base layer and the ZnO cover, so as to achieve the above-mentioned difference in layer's crystallography. The plasma close to the substrate may be generated and maintained by RF biasing the substrate; different plasma densities are obtained by modifying the RF power density applied to the substrate. In this context, “RF biasing” means application of an RF electromagnetic signal to the substrate during the growth of the ZnO sublayers thereon. This RF biasing signal is typically a low-power and low-voltage signal in comparison with any RF signal applied to the sputtering target (in case of RF sputtering). The surface power density resulting on the substrate due to the application of the biasing RF signal is typically substantially lower (e.g., units of 10⁻²Wcm⁻³), than the surface power density on the sputtering target (e.g., units of Wcm⁻³). Consequently, the plasma density established in the vicinity of the growing ZnO layer will be significantly lower than the density of the primary plasma at the sputtering target (lower than about 10⁸ cm⁻³). It shall be noted that, in the context of the present document and in accordance with constant practice in the technical field, plasma density designates the plasma density (density of free electrons) averaged over several (e.g. 10 to 20) cycles of any generating RF field rather than the instantaneous plasma density. In that sense, the “plasma density” may be termed “effective plasma density”. Other than by RF biasing, the plasma close to the substrate could also be obtained and maintained by directing the primary plasma from the region close to the sputtering target using a solenoid or in any other way.

The above-described method exploits the phenomenon of the crystalline texture of ZnO being dependent on plasma density close to the substrate. It has been shown, for instance, that RF biasing conditions influence the crystalline texture of ZnO (see e.g. S. Tiakayanagi et al., “c-axis parallel oriented ZnO film depositions by variable frequency RF bias sputtering,” Proc. of Symposium on Ultrasonic Electronics, Vol. 31 (2010) pp. 509-510.).

The plasma densities close to the substrate are preferably chosen such that the ZnO base layer is deposited with a preferred crystallographic orientation and that the ZnO cover is deposited with a crystallographically randomly oriented or amorphous structure or with a preferred crystallographic orientation different from the preferred crystallographic orientation of the base layer. The ZnO cover may consist of a single ZnO layer or comprise plural sublayers.

According to an embodiment of the method, the plasma density at the substrate is maintained constant during the deposition of the ZnO base layer. The plasma density close to the substrate can also be held constant during the deposition of the ZnO cover after a unique variation that causes a change in the crystallographic state of the growing nominally undoped ZnO.

Additionally or alternatively, the plasma density at the substrate may be varied during the deposition of the ZnO cover. According to an embodiment, the plasma density close to the substrate is maintained constant after one or more of the variations in such a way as to achieve a multilayer cover comprising plural ZnO sublayers with different crystallographic properties (i.e. different textures). Part or all of the variations of the plasma density close to the substrate may be carried out with an amplitude and frequency such that single preferred crystallographic orientation or a crystallographically randomly oriented or amorphous structure of the deposited ZnO results. It may be noted that ZnO growth with a preferred crystallographic orientation typically results when the plasma density close to the substrate is substantially constant. Nevertheless, by rapidly changing the plasma density close to the substrate, it is also possible to arrive at a single preferred crystallographic orientation or to a more random distribution of the orientations of the crystallographic domains or even an amorphous material structure.

It will be appreciated that the present method of manufacturing a transparent conducting film can use a relatively simple setup, especially if the plasma close to the substrate is generated by RF biasing. In comparison with processes that use inductively-coupled plasma to make the ZnO deposit conductive and that require a complex deposition apparatus geometry including a solenoid positioned within the deposition chamber, maintenance and operation costs can be avoided by using the method proposed herein. It will further be appreciated that separate post-deposition treatment by hydrogen or UV light to make the ZnO film conducting is not necessary (but not excluded a priori).

### BRIEF DESCRIPTION OF THE DRAWINGS

By way of example, preferred, non-limiting embodiments of the invention will now be described in detail with reference to the accompanying drawings, in which:

FIG. 1: is a schematic transversal cross-sectional view of a transparent conducting film;

FIG. 2: is a schematic transversal cross-sectional view of further transparent conducting film;

FIG. 3: is a schematic transversal cross-sectional view of yet another transparent conducting film;

FIG. 4: is a schematic drawing of a deposition apparatus,

FIG. 5: is a power delivery scheme for the deposition of a transparent conducting ZnO film;

FIG. 6: is a power delivery scheme for the deposition of another transparent conducting ZnO film;

FIG. 7: is a transversal SEM image of an example of a transparent conducting ZnO film according to the invention;

FIG. 8: is a graph illustrating the transmittance of the ZnO film depicted in FIG. 7;

FIG. 9: is a diagram of the evolution of the resistivity of a ZnO film similar to that in FIG. 7 monitored over several thousands of hours of heating in comparison with other ZnO films.

### DETAILED DESCRIPTION PREFERRED EMBODIMENTS

Preferred embodiments of the present invention relate to a nominally undoped ZnO layer structure that is highly conducting, has a high VIS and NIR transparency (with respect to ZnO:Al films), but which possesses a significantly improved environmental stability (with respect to conventional conducting ZnO films).

The ZnO transparent conducting film comprises of two principal parts:
i) a thicker base layer made of a nominally undoped and crystallographically highly ordered ZnO layer, and
ii) a thinner cover structure consisting of a single ZnO sublayer or a multilayered ZnO stack.

In the cover, at least one of the ZnO sublayers has a crystallographically randomly oriented or amorphous structure or a preferred crystallographic orientation different from the preferred crystallographic orientation of the base layer.

While the thicker base layer assures the optoelectrical performance (e.g., high conductivity and high VIS and NIR transparency), the primary function of the ZnO cover is to slow down or inhibit penetration of corroding agents towards and within the underlying base layer.

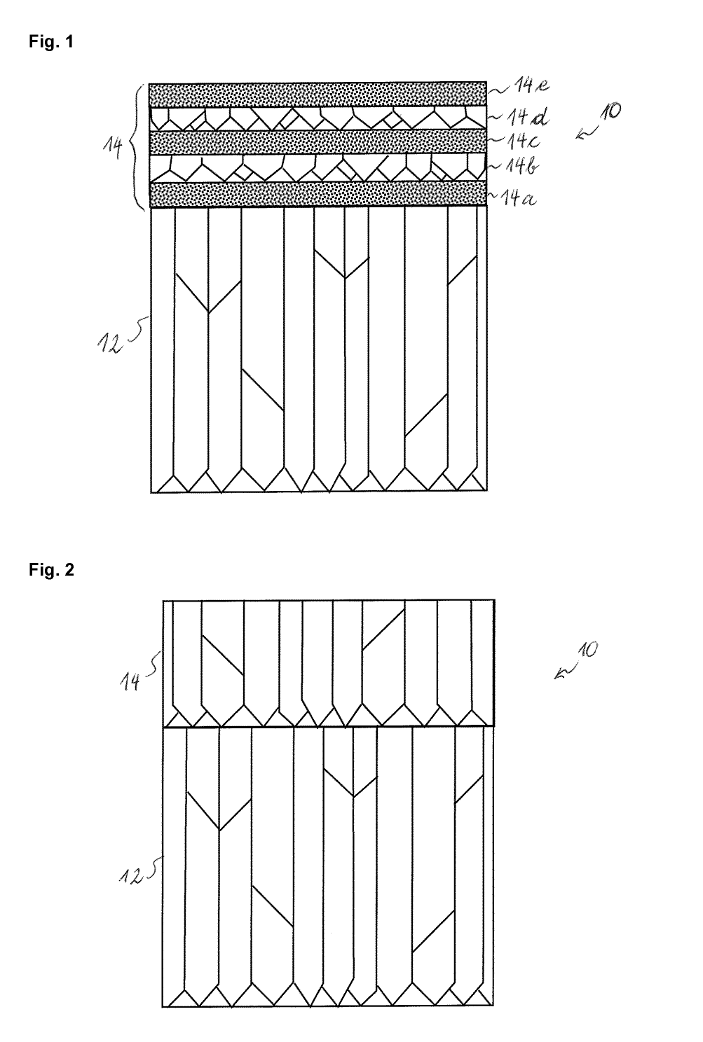

A scheme of a first example of TCO film 10 using the suggested ZnO is offered in FIG. 1. The ZnO base layer 12 consists of a comparatively thick layer of pure ZnO exhibiting the commonly observed columnar microstructure featuring numerous columns that enlarge upwards in width during film growth from underlying substrate (not shown). The column boundaries that span through the height (thickness) of the ZnO base layer 12 represent possible routes for corroding agents, which may at least partly be responsible for degradation of the conductivity when the ZnO base is exposed to harsh environmental conditions, alongside the grain boundaries and other imperfections exposed at the film's surface. The cover layer 14 consists of a stack of several thinner ZnO sublayers 14a, 14b, 14c, a4d, 14e from which at least one has a different preferred crystallographic orientation than the base layer 12. In the example of FIG. 1, the preferred crystallographic orientations of the individual sublayers 14a, 14b, 14c, a4d, 14e are all different from that of the ZnO base layer 12, but that is not a requirement. The ZnO cover 14 provides a diffusion barrier to water and other corroding agents. Indeed, the chemically active substances have to travel through complex (tortuous) paths in order to reach and react with the underlying base layer 12.

FIG. 2 schematically shows a second example of a TCO film 10, wherein the ZnO base layer 12 is the same as in FIG. 1 but the ZnO cover 14 is provided by a monolayer having a preferred crystallographic orientation that is different from the one of the base layer 12. (This does not result in a different orientation of the columnar structures.)

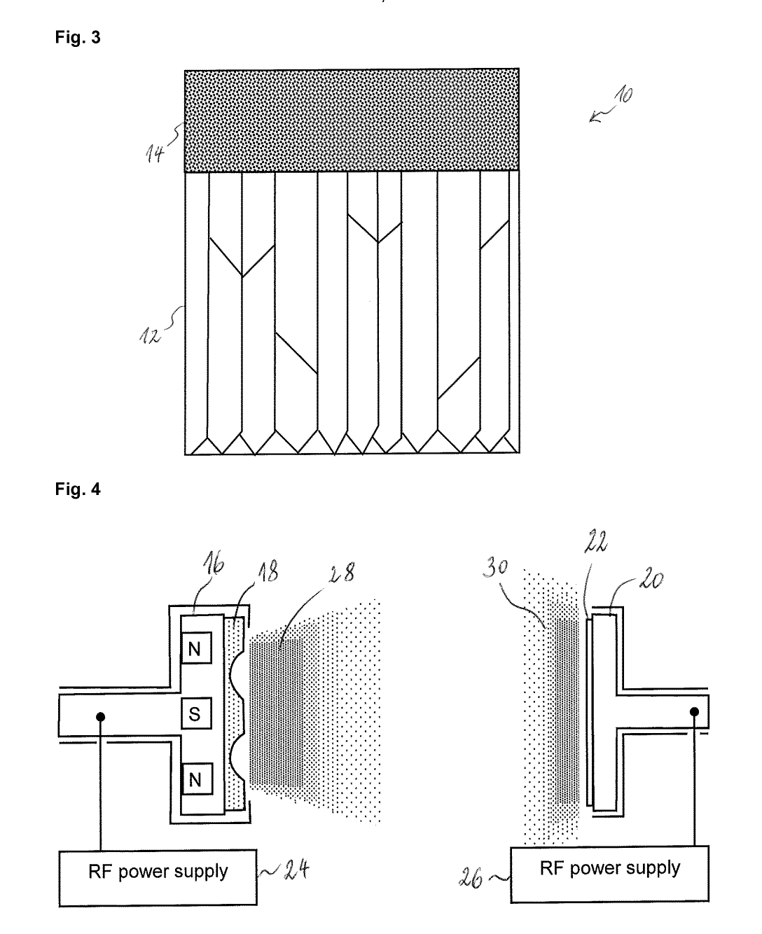

FIG. 3 schematically shows a third example of a TCO film 10. The ZnO base layer 12 is again the same as in FIG. 1 but the ZnO cover 14 is provided by a monolayer having a crystallographically randomly oriented or amorphous structure.

The transparent conducting film structure illustrated in FIGS. 1 to 3 can be prepared in an RF magnetron sputtering process with an additional RF discharge to increase and maintain an elevated plasma density above the substrate holder onto which the sputtered vapours condensate. A schematic illustration of a deposition apparatus is provided in FIG. 4. FIG. 4 illustrates an interior of a vacuum vessel (or chamber—not shown) that features a magnetron 16 with a highly pure ceramic ZnO target 18 and an RF-power biasable and rotatable sample holder 20 into which the substrate 22 can be mounted. The purity of the ZnO target preferably amounts to 99.99 at-% (atomic percent). The deposition apparatus further comprises a pumping system (including, e.g., a turbomolecular pump, not shown) capable of generating high vacuum (pressures below about 10⁻³ Pa) and a controllable working gas inlet (not shown), a pressure control system, and two independent RF generators 24, 26 for power delivery to the sputtering target and the substrate holder, respectively. As an alternative to using two RF generators, one could use a single RF generator capable of delivering power independently on (at least) two separate channels. The working gas may be an inert gas (usually Ar of high-grade purity, e.g. 99.999 at-%). Instead of sputtering from a ZnO target, one could also use a Zn target but in this case the deposition has to take place in a reactive atmosphere providing oxygen atoms.

Prior to starting the deposition, the pressure within the vessel should be low enough to eliminate any unwanted impurities, e.g. lower than 10⁻³ Pa. During the deposition of the film, Ar working gas is leaked into the vacuum vessel in a controllable fashion, e.g. at the rate of 25 sccm (standard cubic centimetres per minute). During the entire deposition process, pressure inside the vessel is kept at about 10⁻¹ Pa by balancing the inflow of Ar gas and the pumping speed of the pump.

During deposition, the substrate is rotated around the central axis of the substrate holder so as to improve the condensing layer's homogeneity. Deposition is carried out at ambient temperature (about 18° C. to 25° C.). The substrate is not heated otherwise than by the incoming plasma-originated radiation (which somewhat raises temperature on the substrate surface above the room temperature, e.g. by about 10-20° C.). The substrate and the substrate holder are electrically isolated from the remaining chamber, in order to permit their biasing by the second RF power generator 26.

During the deposition process, the ZnO target is bombarded by Ar ions generated within the dense plasma 28, magnetically confined close to the target, excited by the “primary” discharge. This discharge is powered by the first RF generator 24. In a test example, a power of 140 W was applied to a 7.5 cm diameter target during the entire deposition process, which corresponded to an average target power density of approximately 2.75 Wcm⁻². The ZnO film forms by condensation of the sputtered species onto the substrate 22 placed atop the sample holder 20 that is itself positioned facing the sputtering target at about 13 cm distance. ZnO films grown in these conditions are highly resistive (p>10³ 0 cm) unless they are exposed to an additional RF power-driven “secondary” plasma discharge 30 maintained above the substrate 22. The optimal power density of the secondary discharge, P_{b}, that should be delivered to the substrate in order to obtain ZnO films with resistivity values around or below 10⁻³ 0 cm is about P_{b}=15·10⁻³ Wcm⁻². This capacitively-coupled RF discharge causes a self-induced negative DC voltage (bias), U_{b}, at the substrate holder. In the test example, at P_{b}=15·10⁻³ Wcm⁻², this bias was measured to be approximately U_{b}=−25 V.

During the first processing step (corresponding to the deposition of the ZnO base layer) the RF power delivery to both sputtered target (primary discharge) and to the substrate holder (secondary discharge) are kept constant during a period of time sufficient to obtain a ZnO layer of the desired thickness (e.g. in the range from 300 to 1500 nm). ZnO films obtained under the above biasing conditions (P_{b}=15·10⁻³ Wcm⁻²) possesses a highly ordered hexagonal structure (wurtzite) that typically exhibits a (001) texture (i.e., the c-axis of hexagonal crystals is oriented perpendicular to the substrate plane), independently on the type of substrate (crystalline or amorphous).

In the second processing step (employed for formation of the ZnO cover), the discharge close to the sputtering target is kept constant (using the same parameters as in the first processing step), but the driving power of the secondary discharge maintained above the sample holder is varied in a repetitive manner in between two extremal values. In the test example, the extremal values were P_{b}=15·10⁻³ Wcm⁻² (resulting in U_{b}=−25 V) and P_{b}=65.10⁻³ Wcm⁻² (resulting in Ub=−100 V). The particular selection of these two biasing power values is related to the preferred crystallographic orientation (texture) of the growing ZnO sublayers: at 15·10⁻³ Wcm⁻², a strong ZnO (001) texture can be achieved, while at P_{b}=65·10⁻³ Wcm⁻² a ZnO (110) texture is obtained. At higher P_{b} values (e.g., P_{b}=12.10⁻² Wcm⁻²) a ZnO (101) texture can also be obtained. The textures of the prepared layers can be verified, e.g., by θ-2θ X-ray diffraction (XRD) analysis.

In the first fabrication step, in which the base layer is formed, the density of the plasma above the growing ZnO film is maintained at a level such that a highly conducting ZnO film with a preferred crystallographic orientation is obtained. In the second fabrication step, in which the ZnO cover is formed, the density of the plasma above the growing ZnO film is altered in such a way as to induce a distinct modification in the crystallographic order of the film under preparation, with respect to the crystallographic order of the base layer. The density of the (secondary) plasma can be modified abruptly or in a gradual manner, depending on the targeted ZnO cover microstructure. With abrupt (stepwise) modulation of the secondary RF power between substantial intervals of constant applied power, distinct ZnO sublayers with different textures can be obtained. By stepwise or abrupt modulation it is meant that P_{b} is altered from one extremal value to another within a time less than 1 to 2 minutes. With gradual modulation of the secondary RF power, inner boundaries of the ZnO cover may become less distinguishable or disappear completely.

The frequency of gradual or stepwise P_{b} modulations between two extremal values also has an impact on the microstructure: when the frequency of the modulation increases, the height (thickness) of ZnO sublayers deposited under the same conditions decreases. At higher frequencies of the modulation of the secondary RF power, the biasing conditions may “average out”, so that a single preferred crystallographic orientation develops. Nevertheless, it is also possible that a crystallographically randomly oriented or amorphous structure can be obtained.

The crystallographic state of the resulting film is thus affected by i) the selected extremal values of P_{b}, ii) the rate of P_{b} alteration, and iii) the time(s) during which the secondary discharge is kept steady—i.e., by the time(s) during which the growing ZnO films can develop their proper textures. The ZnO cover can thus consist of multiple thin ZnO films of altered preferred crystallographic orientations only if the power delivery to the secondary discharge remains substantially constant in-between the alterations for sufficiently long time(s), e.g., several minutes or more. It is of interest to keep the thickness of the individual sublayers of the ZnO cover relatively thin (e.g., thinner than 20 nm), in order to permit a larger amount of preferred crystallographic orientation alterations over the entire height of the cover. The interface in between the two adjacent sublayers is defined by the rate of P_{b} alteration. A neat interface is obtained if the modification in power amplitude abrupt. A gradual or smeared-out interface is obtained if the transition in power amplitude is slow (e.g., if P_{b} is modified on a timescale of several minutes).

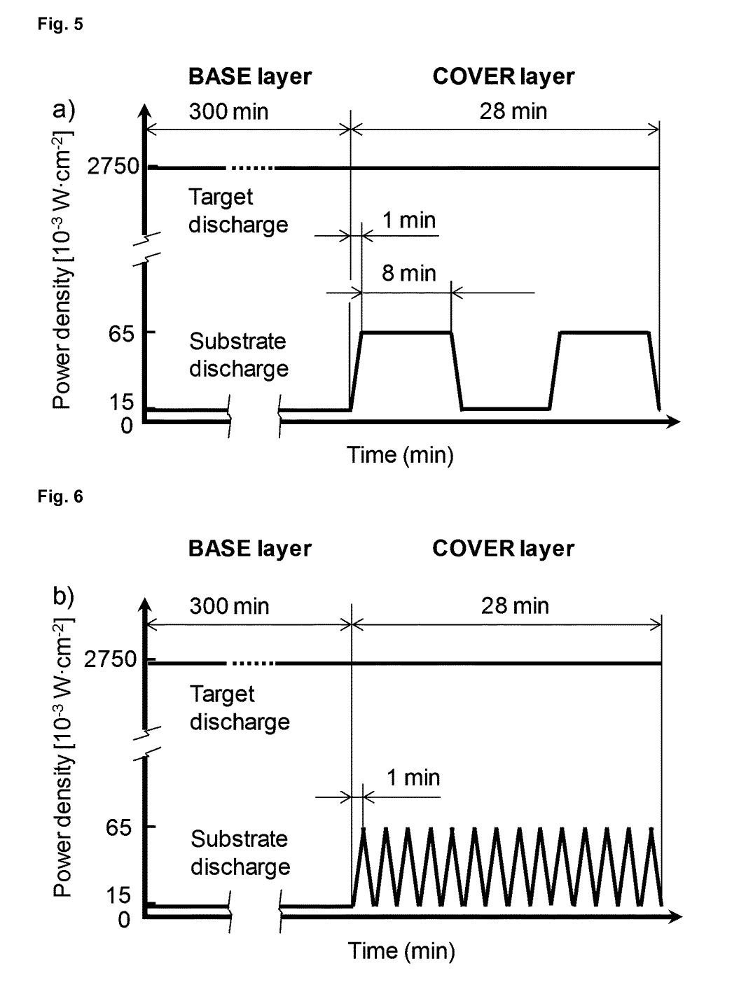

FIG. 5 shows a power delivery scheme for both target and substrate discharges that can be used to fabricate a transparent conducting film with a (001)-oriented ZnO base layer topped by a multilayer ZnO cover. In FIG. 5, during the deposition of the ZnO cover, the power density of the secondary discharge is ramped from P_{b}=15.10⁻³ Wcm⁻² up to P_{b}=65.10⁻³ Wcm⁻² and then back to P_{b}=15′10⁻³ Wcm⁻², with plateaux of 8 minutes in duration at each of these extremal values. The resulting sublayers of the cover are expected to have different textures, e.g., alternating (110) and (001) textures.

FIG. 6 shows another power delivery scheme for both target and substrate discharges that can be used to fabricate a transparent conducting film with a (001)-oriented ZnO base layer topped by a ZnO cover, wherein the secondary RF discharge operated above the substrate is varied periodically and in a continuous manner without plateaux at the selected extremal values. In other words, the ramp-up and ramp-down phases follow one another directly. In FIG. 6, during the deposition of the ZnO cover the power density of the secondary discharge is ramped from P_{b}=15.10⁻³ Wcm⁻² up to P_{b}=65·10⁻³ Wcm⁻² and then immediately back to P_{b}=15.10⁻³ Wcm⁻². The resulting ZnO cover microstructure has a unique (110) texture with an abrupt interface with the underlying ZnO base layer.

### Example

A prototype of a transparent conducting film was produced under the deposition conditions described hereinbefore, using the two RF power delivery scheme presented in FIG. 6.

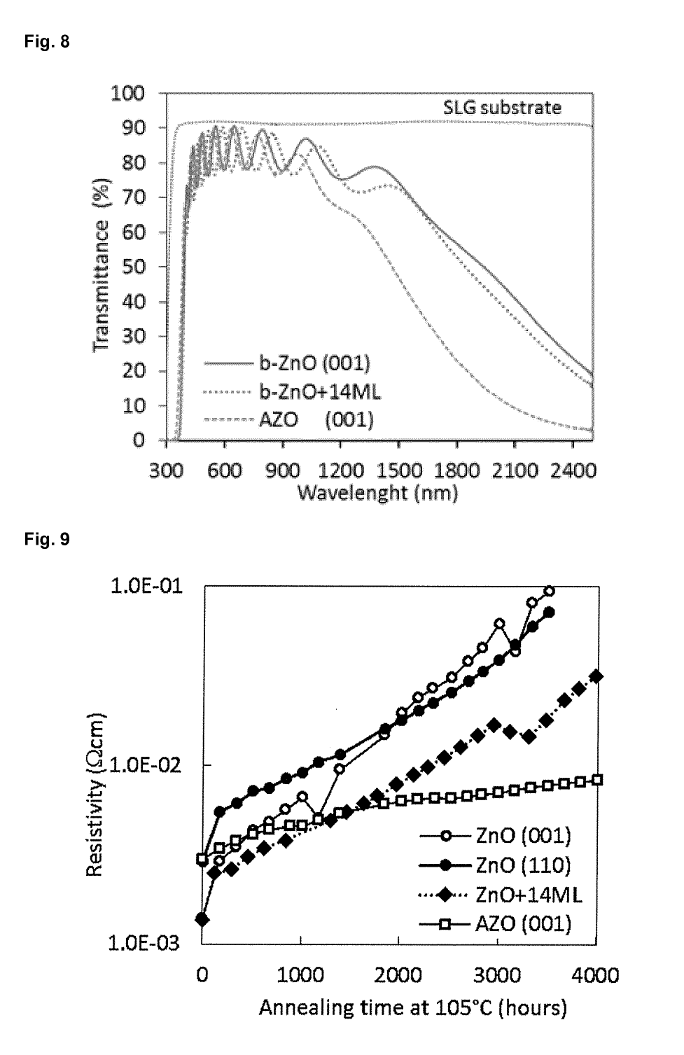

During the fabrication of the respective film structure, the primary RF discharge at the target was operated in pure Ar at 1.3.10⁻¹ Pa working pressure, the power delivery being kept at 2.75 Wcm⁻². In the first processing step the secondary discharge excited above the substrates by means of the second RF power supply was also kept constant at P_{b}=15.10⁻³ Wcm⁻². The deposition was carried out on a soda lime glass substrate. The resulting ZnO base layer had a thickness of 770 nm and a resistivity of 1.4·10⁻³ Ω cm. It is to be noted that this resistivity is identical to that of the AZO film of comparable thickness and prepared in the same conditions. However, a lower resistivity values can be reached in the optimized deposition conditions (e.g. a higher substrate temperature). The plasma wavelength deduced from absorbance analyses performed on ZnO films prepared in identical conditions is close to 2500 nm which assures good NIR transparency (in contrast to the AZO film of comparable thickness, which has its plasma wavelength at 2200 nm), as also depicted in FIG. 8. θ-2θ XRD analyses also performed on the ZnO films prepared in identical conditions suggest a strong (001) texture, as indicated by very pronounced (002) and (103) diffractogram reflection peaks that are both fingerprints of (001) texture.

In the second processing step, the secondary RF discharge above the substrate holder was altered in a continuous manner in between the two extremal values at P_{b}=15.10⁻³ Wcm⁻² and P_{b}=65.10⁻³ Wcm⁻², with a 1-minute-long ramping intervals as shown in FIG. 6. The total number of cycles (ramping up-ramping down) was 14.

The deposited cover layer had a thickness of 75 nm. Its microstructure possesses a unique (110) crystallographic texture (sublayers were not discernible using scanning electron microscope (SEM) imaging). The microstructure was checked by θ-2θ XRD analysis on another thicker sample of the cover layer applied directly on the substrate in a separate experiment using identical deposition conditions except of the larger amount of ramping up-ramping down cycles (70 cycles).

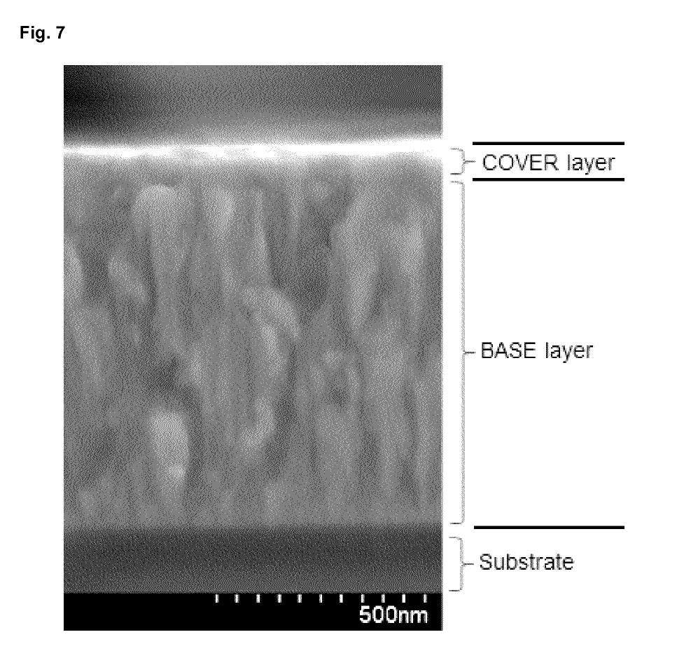

FIG. 7 shows a cross-sectional SEM (scanning electron microscopy) image of the transparent conducting film of the example. The resistivity of this transparent conducting film as a whole is approximately equal to that of the ZnO base layer on its own: 1.4·10⁻³ Ω cm.

FIG. 8 shows a transmittance analysis obtained by UV-VIS-NIR spectrophotometry for the ZnO transparent conducting film depicted in FIG. 7, in comparison with a) a single layer ZnO film having (001) crystallographic texture (“ZnO (001)”), and b) a standard ZnO:Al (AZO) film (“AZO (001)”). All samples had about the same thickness as the “ZnO+14ML” film.

It can be observed that both single layer “ZnO (001)” film and multilayer “ZnO+14ML” film have substantially higher transmittance in the NIR spectral region than the “AZO (001)” film. This is their principal asset of commercial interest.

The environmental stability of another prototype ZnO structure was tested in the ambient air and also by the annealing in the environmental chamber that was filled with hot air at 105° C. The only difference between the tested prototype and that of FIG. 7 is that the thickness of the base layer is 275 nm rather than 770 nm. FIG. 9 depicts the resistivity rise monitored during several thousands of hours of heating for the ZnO transparent conducting film similar to the above example (“ZnO+14ML”), in comparison with a) a single layer ZnO film having (001) crystallographic texture (“ZnO (001)”), b) a single layer ZnO film having (110) crystallographic texture (“ZnO (110)”), and c) a standard ZnO:Al (AZO) film (“AZO (001)”). All samples had about the same thickness as the base layer of the “ZnO+14ML” film.

It can be observed that the transparent conducting film “ZnO+14ML” exhibits a much lower resistivity rise related to heat-induced degradation than its single layer ZnO counterparts. For instance, after the first 3000 hours the resistivity of the “ZnO+14ML” film increased 12 times while the resistivity of the “ZnO (001)” film and the “ZnO (110)” film increased 45 times and 28 times, respectively. This indicates a significantly improved environmental stability due to the presence of the ZnO cover. Nevertheless, the resistivity rise of the AZO film was lower (2.4 times).

It was furthermore verified over a period of six months that the transparent conducting film of the example has excellent stability in ambient air.

Last but not least, ageing of a transparent conducting film according to the invention in damp heat (DH) environment will prove its enhanced stability in harsh environment combining both elevated temperature and high humidity.

While specific embodiments have been described herein in detail, those skilled in the art will appreciate that various modifications and alternatives to those details could be developed in light of the overall teachings of the disclosure. Accordingly, the particular arrangements disclosed are meant to be illustrative only and not limiting as to the scope of the invention, which is to be given the full breadth of the appended claims and any and all equivalents thereof.

1-23. (canceled)

24. A transparent conducting film comprising a nominally undoped conducting ZnO base layer, the ZnO base layer having a preferred crystallographic orientation and being covered with a ZnO cover, the ZnO cover comprising one or more ZnO sublayers, of which at least one has a crystallographically randomly oriented or amorphous structure or has a preferred crystallographic orientation different from the preferred crystallographic orientation of the base layer.

25. The transparent conducting film as claimed in claim 24, wherein the ZnO cover consists of a single ZnO sublayer having a crystallographically randomly oriented or amorphous structure.

26. The transparent conducting film as claimed in claim 24, wherein the ZnO cover consists of a single ZnO sublayer having a single preferred crystallographic orientation.

27. The transparent conducting film as claimed in claim 24, wherein the ZnO cover is a multilayer cover comprising plural ZnO sublayers, and wherein the ZnO sublayers of the ZnO cover have different preferred crystallographic orientations.

28. The transparent conducting film as claimed in claim 27, wherein at least one of the ZnO sublayers of the ZnO cover has a crystallographically randomly oriented or amorphous structure.

29. The transparent conducting film as claimed in claim 27, wherein at least one of the plural ZnO sublayers of the ZnO cover has a thickness comprised in the range from 2 nm to 40 nm and the ZnO cover has an overall thickness comprised in the range from 10 nm to 200 nm.

30. The transparent conducting film as claimed in claim 24, wherein the ZnO cover is arranged in direct contact with the ZnO base layer.

31. The transparent conducting film as claimed in claim 24, wherein the base layer surface has a normal, wherein the preferred crystallographic orientation of the ZnO base is (001) with respect to the normal.

32. The transparent conducting film as claimed in claim 24, wherein the base layer surface has a normal, wherein the preferred crystallographic orientation of at least one of the ZnO sublayers of the ZnO cover is (110) or (101) with respect to the normal.

33. The transparent conducting film as claimed in claim 24, comprising a flexible substrate carrying the ZnO base layer and the ZnO cover applied thereon.

34. A semiconductor device comprising a transparent conducting film as claimed in claim 24.

35. The semiconductor device as claimed in claim 34, wherein the semiconductor device comprises one or more of a transparent transistor, an array of transparent transistors, a flat panel display, an RFID chip, a photovoltaic cell and a capacitive sensor.

36. The semiconductor device as claimed in claim 34, comprising a thin-film solar cell.

37. A method of manufacturing a transparent conducting film comprising a nominally undoped conducting ZnO base layer, the ZnO base layer having a preferred crystallographic orientation and being covered with a ZnO cover, the ZnO cover comprising one or more ZnO sublayers, of which at least one has a crystallographically randomly oriented or amorphous structure or has a preferred crystallographic orientation different from the preferred crystallographic orientation of the base layer, the method comprising depositing a nominally undoped conducting ZnO base layer and a nominally undoped ZnO cover on the ZnO base by sputtering from a ZnO target in an inert gas atmosphere or from a Zn target in a mixed oxygen and inert gas atmosphere onto a substrate while maintaining a plasma close to the substrate; wherein the deposition of the ZnO base layer and the deposition of the ZnO cover are carried out with different densities of the plasma close to the substrate.

38. The method as claimed in claim 37, wherein the plasma densities close to the substrate are chosen such that the ZnO base layer is deposited with a preferred crystallographic orientation and that the ZnO cover is deposited with a crystallographically randomly oriented or amorphous structure or with a preferred crystallographic orientation different from the preferred crystallographic orientation of the ZnO base layer.

39. The method as claimed in claim 37, wherein the plasma density close to the substrate is maintained constant during the deposition of the ZnO base layer.

40. The method as claimed in claim 37, wherein the plasma density close to the substrate is maintained constant during the deposition of the ZnO cover.

41. The method as claimed in claim 37, wherein the plasma density close to the substrate is varied during the deposition of the ZnO cover.

42. The method as claimed in claim 41, wherein the plasma density close to the substrate is maintained constant after one or more of the variations in such a way as to achieve a multilayer cover comprising plural ZnO sublayers with different crystallographic properties.

43. The method as claimed in claim 41, wherein at least part of the variations of the plasma density close to the substrate are carried out with an amplitude and frequency such that a single preferred crystallographic orientation or a crystallographically randomly oriented or amorphous structure of the deposited ZnO results.

44. The method as claimed in claim 37, wherein the plasma at the substrate is generated and maintained by RF biasing the substrate, and wherein the different plasma densities are obtained by modifying RF power density applied to the substrate.
